(19) United States
(12) Patent Application Publication
(10) Pub. No.: US 2025/0132275 A1
(43) Pub. Date: Apr. 24, 2025

(54) SEMICONDUCTOR PACKAGE

(71) Applicant: Samsung Electronics Co., Ltd., Suwon-si (KR)

(72) Inventors: Sangho Cha, Suwon-si (KR); Yunrae Cho, Suwon-si (KR)

(21) Appl. No.: 18/909,082

(22) Filed: Oct. 8, 2024

(30) Foreign Application Priority Data
Oct. 23, 2023 (KR) 10-2023-0142341
Nov. 14, 2023 (KR) 10-2023-0157690

(51) Int. Cl. H01L 23/00; H01L 25/065; H10B 80/00

(52) U.S. Cl. CPC H01L 24/05; H01L 24/06; H01L 24/13; H01L 24/16; H01L 25/0657; H01L 2224/0401; H01L 2224/05647; H01L 2224/05666; H01L 2224/0603; H01L 2224/06132; H01L 2224/06515; H01L 2224/13082; H01L 2224/16146; H01L 2225/06541; H01L 2225/06565; H10B 80/00

(57) ABSTRACT

A semiconductor package includes a semiconductor substrate, connection pads on a bottom surface of the semiconductor substrate, and connection bumps respectively on the connection pads, wherein the connection bumps include an extension bump and a non-extension bump, wherein the extension bump includes an extension seed layer on a respective one of the connection pads and a first conductive pillar on the extension seed layer, and wherein the extension seed layer longitudinally extends in a first extension direction.

### CROSS-REFERENCE TO RELATED APPLICATIONS

This application is based on and claims priority under 35 U.S.C. § 119 to Korean Patent Application Nos. 10-2023-0142341, filed on Oct. 23, 2023, and 10-2023-0157690, filed on Nov. 14, 2023, in the Korean Intellectual Property Office, the disclosures of which are incorporated by reference herein in their entirety.

### BACKGROUND OF THE INVENTION

The inventive concepts relate to a semiconductor device, and more particularly, to a semiconductor package including an extension bump.

Warpage may occur in semiconductor chips for various reasons. When a semiconductor chip having warpage is mounted on a mount surface, the distance between the semiconductor chip and the mount surface may not be uniform because of the warpage. For example, when the semiconductor chip is too close to the mount surface, a connection member, such as a solder ball, between the semiconductor chip and the mount surface may overflow and come into contact with another adjacent connection member. When the connection member is in contact with another connection member, failure of a semiconductor device may occur.

To prevent the failure, the sizes of pads and connection members of a semiconductor chip may be reduced. However, if the pads and connection members of a semiconductor chip are excessively miniaturized with the intensive development of semiconductor device manufacturing technology, defects including cracks in the connection members may occur due to the excessive miniaturization.

### SUMMARY OF THE INVENTION

The inventive concepts provide a semiconductor package having increased reliability by reducing or eliminating defects that occur when a semiconductor chip having warpage is used.

The inventive concepts are not limited to those mentioned above, and the inventive concepts that have not been mentioned will be more clearly understood by one of skill in the art from the description below.

According to aspects of the inventive concepts, there is provided a semiconductor package including a semiconductor substrate, connection pads on a bottom surface of the semiconductor substrate, and connection bumps respectively on the connection pads, wherein the connection bumps include an extension bump and a non-extension bump, wherein the extension bump includes an extension seed layer on a respective one of the connection pads and a first conductive pillar on the extension seed layer, and wherein the extension seed layer longitudinally extends in a first extension direction.

According to aspects of the inventive concepts, there is provided a semiconductor package including a first semiconductor chip including a first semiconductor substrate, first connection pads on a bottom surface of the first semiconductor substrate, connection bumps respectively on the first connection pads, and a through silicon via (TSV) extending into the first semiconductor substrate, and a second semiconductor chip on the first semiconductor chip, the second semiconductor chip including a second semiconductor substrate and a TSV extending into the second semiconductor substrate, wherein the connection bumps include an extension bump and a non-extension bump, wherein the extension bump includes an extension seed layer on a respective one of the first connection pads and a first conductive pillar on the extension seed layer, wherein the extension seed layer longitudinally extends in a first extension direction, wherein an angle is defined between the first extension direction and a pitch direction, wherein the pitch direction is a direction in which adjacent ones of the first connection pads are closest to each other, and wherein the angle is in a range from about 60° to about 90°.

According to aspects of the inventive concepts, there is provided a semiconductor package including a first semiconductor chip including a first semiconductor substrate that includes a memory device, first connection pads on a bottom surface of the first semiconductor substrate, connection bumps respectively on the first connection pads, and a through silicon via (TSV) extending into the first semiconductor substrate, a second semiconductor chip on the first semiconductor chip, the second semiconductor chip including a second semiconductor substrate and a TSV extending into the second semiconductor substrate, and a lower substrate on the bottom surface of the first semiconductor substrate, wherein the connection bumps include an extension bump and a non-extension bump, wherein the extension bump is in a first region of the first semiconductor substrate and the non-extension bump is in a second region of the first semiconductor substrate that is different from the first region, wherein the extension bump includes an extension seed layer on a respective one of the first connection pads, a first conductive pillar on the extension seed layer, and a second seed layer between the extension seed layer and the respective one of the first connection pads, wherein the non-extension bump includes a first seed layer on another respective one of the first connection pads, a third seed layer between the first seed layer and the another respective one of the first connection pads, and a second conductive pillar on the first seed layer, wherein the extension seed layer longitudinally extends in a first extension direction, and the first seed layer does not protrude from a side surface of the second conductive pillar in the first extension direction, wherein the first extension direction is perpendicular to a pitch direction, wherein the pitch direction is a direction in which adjacent ones of the first connection pads are closest to each other, wherein the extension seed layer and the first seed layer include copper (Cu), wherein the second seed layer and the third seed layer include titanium (Ti), wherein upper connection pads are on a top surface of the lower substrate, wherein a first connection member is electrically connected between a first one of the upper connection pads and the first conductive pillar and is in contact with the extension seed layer and an end of the first conductive pillar, wherein a second connection member is electrically connected between a second one of the upper connection pads and the second conductive pillar and is in contact with the second conductive pillar, wherein the second connection member is separated from the first seed layer, and wherein a pitch distance that corresponds to a distance between the first conductive pillar in the first region and another conductive pillar closest to the first conductive pillar is in a range from about 50 μm to about 100 μm, and a distance between the bottom surface of the first semiconductor substrate and the top surface of the lower substrate is in a range from about 30 μm to about 70 μm.

### BRIEF DESCRIPTION OF THE DRAWINGS

Embodiments will be more clearly understood from the following detailed description taken in conjunction with the accompanying drawings, in which:

FIG. 1 is a cross-sectional view of a semiconductor package according to some embodiments;

FIG. 2A is a cross-sectional view of the semiconductor package, taken along line Z1-Z1′ in FIG. 1, according to some embodiments;

FIG. 2B is an enlarged view of a region A in FIG. 2A;

FIG. 2C is a cross-sectional view of a semiconductor package according to some embodiments;

FIG. 3A is an enlarged cross-sectional view of an extension bump in FIG. 2B;

FIG. 3B is a cross-sectional view of an extension bump of a semiconductor package, according to some embodiments;

FIG. 4A is a cross-sectional view of the extension bump taken along line X1-X1′ in FIG. 3A;

FIG. 4B is a cross-sectional view of the extension bump taken along line Y1-Y1′ in FIG. 3A;

FIG. 4C is a cross-sectional view of a semiconductor package taken along a line corresponding to line X1-X1′ in FIG. 3A, according to some embodiments;

FIG. 5 is an enlarged cross-sectional view of the extension bump in FIG. 2B;

FIG. 6A is a cross-sectional view of the extension bump taken along line X2-X2′ in FIG. 5;

FIG. 6B is a cross-sectional view of the extension bump taken along line Y2-Y2′ in FIG. 5;

FIG. 6C is a cross-sectional view of a semiconductor package taken along a line corresponding to line X2-X2′ in FIG. 5, according to some embodiments;

FIG. 7 is a cross-sectional view of a semiconductor package taken along a line corresponding to line Z1-Z1′ in FIG. 1, according to some embodiments;

FIG. 8A is a cross-sectional view of a semiconductor package, taken along line Z2-Z2′ in FIG. 8C, according to some embodiments;

FIG. 8B is an enlarged view of a region B in FIG. 8A; and

FIG. 8C is a cross-sectional view of a semiconductor package according to some embodiments.

### DETAILED DESCRIPTION

Hereinafter, example embodiments are described in detail with reference to the accompanying drawings.

The embodiments are provided to fully explain the technical ideas of the inventive concepts to one of ordinary skill in the art. Various changes in form and details may be made in the embodiments and the scope of the inventive concepts are not limited thereto. Rather, these embodiments are provided so that this disclosure will be thorough and complete and will fully convey the scope of the embodiments to those skilled in the art. In the drawings, the thicknesses and sizes of layers may be exaggerated for clarity.

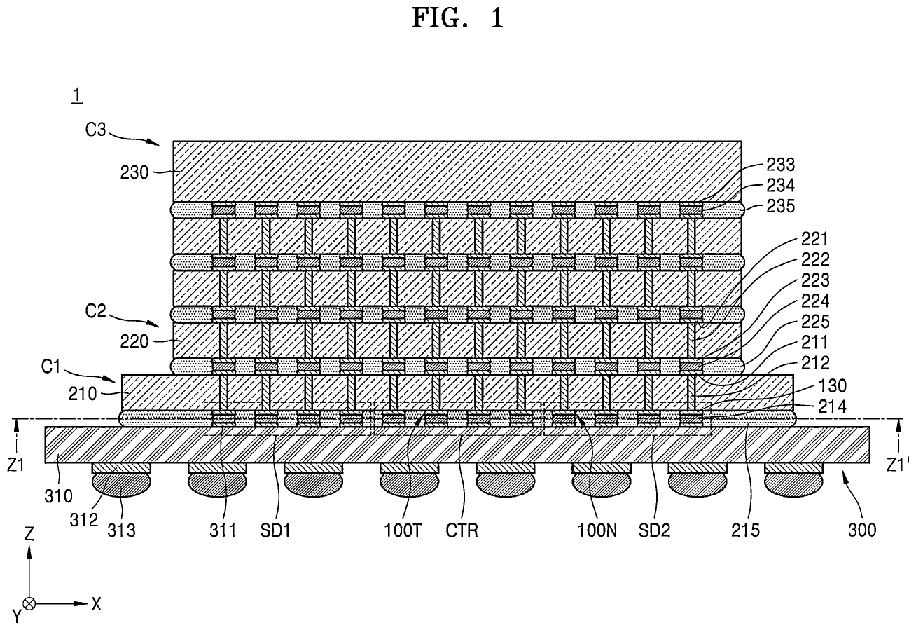

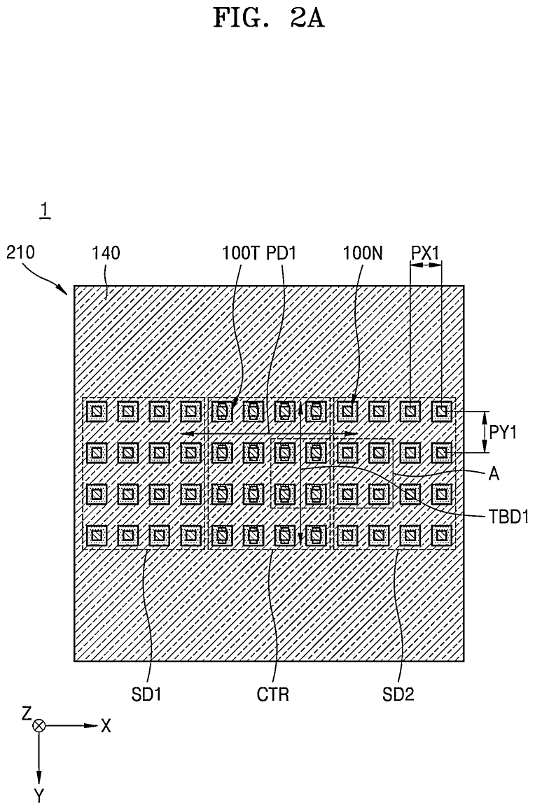

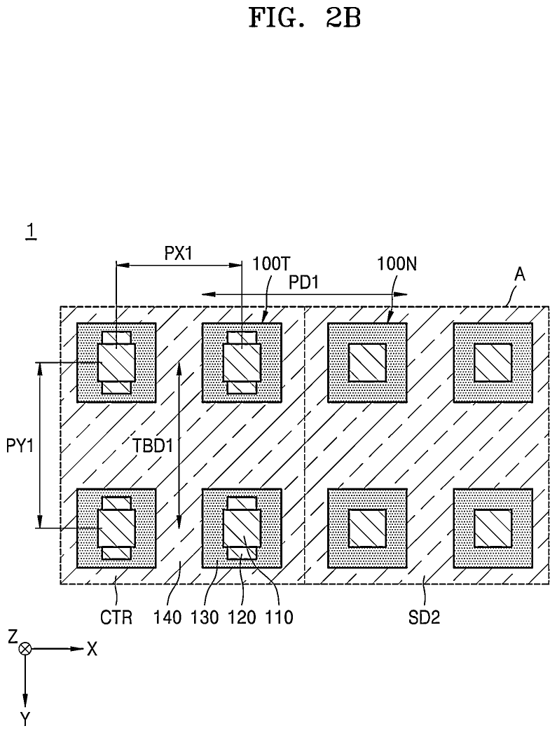

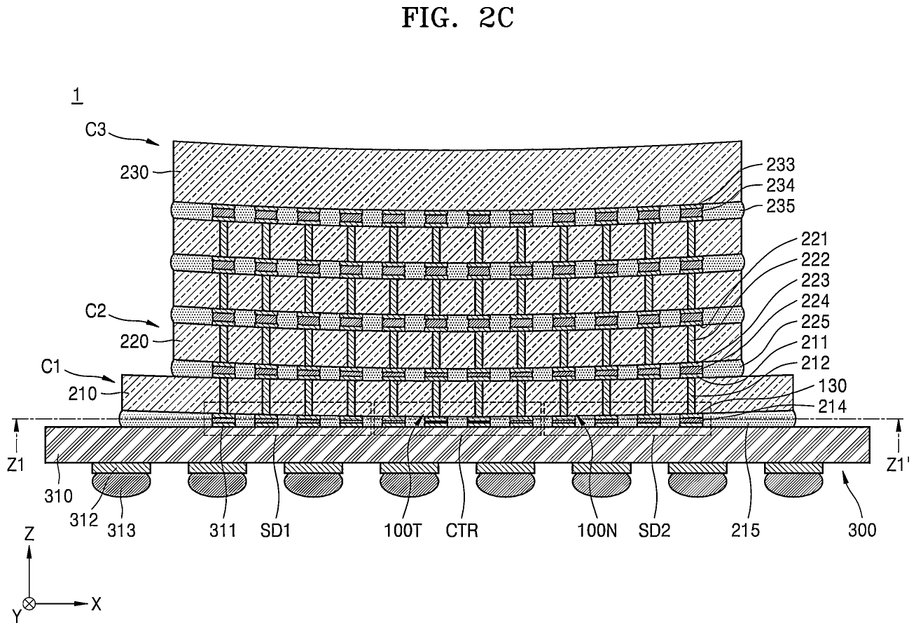

FIG. 1 is a cross-sectional view of a semiconductor package 1 according to some embodiments. FIG. 2A is a cross-sectional view of the semiconductor package 1, taken along line Z1-Z1′ in FIG. 1, according to some embodiments. FIG. 2B is an enlarged view of a region A in FIG. 2A.

As used herein, a first direction refers to the X direction and a second direction refers to the Y direction. The first direction may be perpendicular to the second direction. A third direction refers to the Z direction. The third direction may be perpendicular to the first direction and the second direction. A horizontal plane or a plane refers to an X-Y plane. The top surface of an object refers to a surface thereof in a positive third direction with respect to the object, and the bottom surface of the object refers to a surface thereof in a negative third direction with respect to the object.

Referring to FIG. 1, the semiconductor package 1 may include a first semiconductor chip C1, a second semiconductor chip C2, and a third semiconductor chip C3, which are stacked in the third direction.

The semiconductor package 1 may include a cell region and a pad region. The pad region may be a region in which through electrodes (e.g., 212 and 222), connection pads (e.g., 130, 211, 223, 221, and 233), and connection members (e.g., 214, 224, and 234) are formed for electrical connection among the first to third semiconductor chips C1, C2, and C3. Herein, the through electrodes (e.g., 212 and 222) may also be referred to as through silicon vias (TSVs).

For example, the pad region of the first semiconductor chip CI may include a center region CTR, a first side region SD1, and a second side region SD2. The cell region of the first semiconductor chip C1 may refer to a region other than the pad region in the first semiconductor chip C1. The center region CTR may refer to a bottom portion of the first semiconductor chip C1, in which the horizontal center of the first semiconductor chip C1 is included and a first connection pad 130 is arranged. For example, the center region CTR may include a horizontal center portion of a bottom surface of a first semiconductor substrate 210 of the first semiconductor chip C1. Each of the first side region SDI and the second side region SD2 may refer to a bottom portion of the first semiconductor chip C1, in which the horizontal center of the first semiconductor chip C1 is not included and a first connection pad 130 is arranged. For example, each of the first side region SD1 and the second side region SD2 may include at least a portion of a bottom surface of a first semiconductor substrate 210 of the first semiconductor chip C1 that is laterally spaced apart from a horizontal center portion of the bottom surface of the first semiconductor substrate 210. For example, the center region CTR, the first side region SD1, and the second side region SD2 may be regions of the first semiconductor substrate 210 of the first semiconductor chip C1.

A plurality of first connection pads 130 in the pad region may be arranged in the first direction and the second direction in various layouts. For example, as shown in FIGS. 2A and 2B, the first connection pads 130 may be arranged at a certain pitch in a matrix in the first direction and the second direction in the pad region. Each of the first connection pads 130 may have a quadrilateral shape having a side length in a range from about 30 micrometers (μm) to about 80 μm. However, the shape and arrangement of the first connection pads 130 is not limited thereto. For convenience of illustration, twelve first connection pads 130 are arranged in the first direction and four first connection pads 130 are arranged in the second direction in FIG. 2A, but the number and arrangement of first connection pads 130 is not limited to those shown in FIG. 2A.

For example, each of the first to third semiconductor chips C1, C2, and C3 may correspond to a memory semiconductor chip. For example, the memory semiconductor chip may include a volatile memory semiconductor chip, such as a dynamic random access memory (DRAM) semiconductor chip or a static RAM (SRAM) semiconductor chip, or a non-volatile memory semiconductor chip, such as a phase-change RAM (PRAM) semiconductor chip, a magnetoresistive RAM (MRAM) semiconductor chip, a ferroelectric RAM (FeRAM) semiconductor chip, or a resistive RAM (RRAM) semiconductor chip. In some embodiments, each of the first to third semiconductor chips C1, C2, and C3 may correspond to a high-bandwidth memory (HBM) DRAM semiconductor chip.

Although it is illustrated in FIGS. 1 and 2A that the first to third semiconductor chips C1, C2, and C3 are stacked in the semiconductor package 1, the number of semiconductor chips stacked in the semiconductor package 1 is not limited thereto. For example, 2 to 32 semiconductor chips may be stacked in the semiconductor package 1. In other words, a plurality of second semiconductor chips C2 may be stacked on the first semiconductor chip C1.

Connection bumps may be arranged on the bottom surface of the first semiconductor chip C1. The connection bumps may include an extension bump 100T and a non-extension bump 100N. The extension bump 100T and the non-extension bump 100N are described in greater detail below. The second semiconductor chip C2 may be mounted on the top surface of the first semiconductor chip C1. A second connection member 224 may be between the second semiconductor chip C2 and the first semiconductor chip C1 so that the second semiconductor chip C2 may be electrically connected to the first semiconductor chip C1. The third semiconductor chip C3 may be mounted on the second semiconductor chip C2 and electrically connected to the second semiconductor chip C2 by a third connection member 234.

The first semiconductor chip C1 may include a first semiconductor substrate 210, a first semiconductor device layer, a first through electrode 212, and a first connection pad 130. As shown in FIG. 1, the first semiconductor substrate 210 may include a top surface and a bottom surface opposite to the top surface. The first semiconductor device layer may be formed on the bottom surface of the first semiconductor substrate 210. The bottom surface of the first semiconductor substrate 210 may face a lower substrate 300. For example, the lower substrate 300 may be on the bottom surface of the first semiconductor substrate 210. The first semiconductor device layer may be adjacent to the bottom surface of the first semiconductor substrate 210. The first through electrode 212 may penetrate (i.e., extend into) the first semiconductor substrate 210 and extend from the top to the bottom of the first semiconductor substrate 210 and into the first semiconductor device layer. The first connection pad 130 may be on the bottom surface of the first semiconductor substrate 210 and electrically connected to the first through electrode 212.

For example, the first semiconductor substrate 210 may include silicon (Si). For example, the first semiconductor substrate 210 may include a semiconductor element, e.g., germanium (Ge), or a compound semiconductor, such as silicon carbide (SiC), gallium arsenide (GaAs), indium arsenide (InAs), or indium phosphide (InP). The first semiconductor substrate 210 may have a silicon-on-insulator (SOI) structure. For example, the first semiconductor substrate 210 may include a buried oxide (BOX) layer. The first semiconductor substrate 210 may include a conductive region, e.g., an impurity-doped well or an impurity-doped structure. The first semiconductor substrate 210 may have various isolation structures, such as a shallow trench isolation (STI) structure. For example, the first semiconductor substrate 210 may include a memory device.

The first semiconductor device layer may include various kinds of individual devices and an interlayer insulating film. The individual devices may include various microelectronic devices, e.g., a metal-oxide-semiconductor field effect transistor (MOSFET) such as a complementary metal-oxide-semiconductor (CMOS) transistor, a system large scale integration (LSI), flash memory, DRAM, SRAM, electrically erasable and programmable ROM (EEPROM), PRAM, MRAM, RRAM, an image sensor such as a CMOS image sensor (CIS), a micro-electro-mechanical system (MEMS), an active element, and a passive element. The individual devices may be formed in the first semiconductor device layer in the cell region and electrically connected to the conductive region of the first semiconductor substrate 210. The first semiconductor device layer may further include a conductive wiring or plug, which electrically connects the individual devices or at least two individual devices to the conductive region of the first semiconductor substrate 210. Each of the individual devices may be electrically isolated from other individual devices by a dielectric film.

The first through electrode 212 may penetrate (i.e., extend into) the first semiconductor substrate 210 and extend from the top to the bottom of the first semiconductor substrate 210 and into the first semiconductor device layer. At least a portion of the first through electrode 212 may have a pillar shape. The first through electrode 212 may include a barrier film formed on the surface of the pillar shape and a buried conductive layer filling the inside of the barrier film. The barrier film may include at least one material selected from the group consisting of Ti, TiN, Ta, TaN, Ru, Co, Mn, WN, Ni, and NiB. The buried conductive layer may include at least one material selected from the group consisting of Cu alloys, such as Cu, CuSn, CuMg, CuNi, CuZn, CuPd, CuAu, CuRe, and CuW, W, W alloys, Ni, Ru, and Co.

The first connection pad 130 may be arranged on the bottom surface of the first semiconductor substrate 210 and may be electrically connected to a wiring structure of the first semiconductor device layer. The first connection pad 130 may be electrically connected to the first through electrode 212. The first connection pad 130 may include at least one selected from the group consisting of aluminum (Al), copper (Cu), nickel (Ni), tungsten (W), platinum (Pt), and gold (Au).

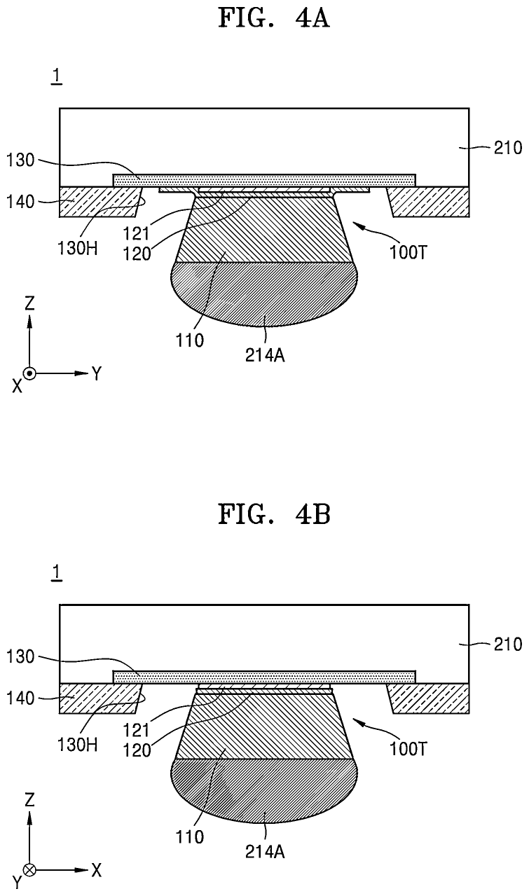

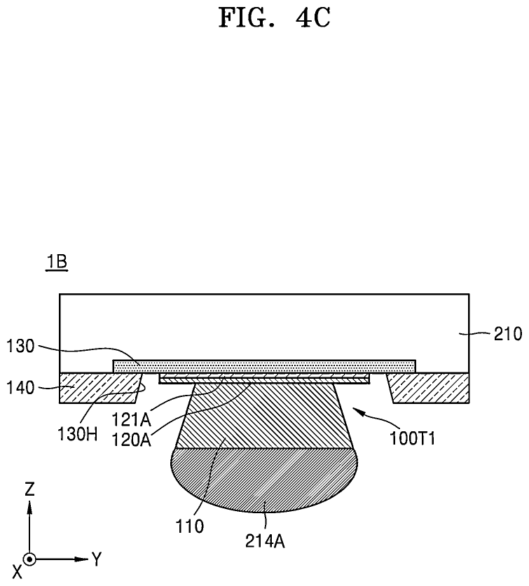

A first protective layer 140 may be formed on the bottom surface of the first semiconductor substrate 210 and may be on (e.g., may cover) at least a portion of the first connection pad 130. The first protective layer 140 may protect the first semiconductor device layer from an external impact or moisture. For example, the first protective layer 140 may include an inorganic insulating film or an organic insulating film. In some embodiments, the first protective layer 140 may include silicon nitride. A hole 130H may be formed in the first protective layer 140 and may expose at least a portion of the top surface of the first connection pad 130. The hole 130H is illustrated in FIGS. 4A to 4C.

A first upper connection pad 211 may be formed on the top surface of the first semiconductor substrate 210 and electrically connected to the first through electrode 212. The first upper connection pad 211 may include at least one selected from the group consisting of aluminum (Al), copper (Cu), nickel (Ni), tungsten (W), platinum (Pt), and gold (Au).

A connection bump may be on the first connection pad 130. The connection bump may be on the bottom surface of the first semiconductor substrate 210. The connection bump may correspond to a chip-substrate connection bump used to mount the first semiconductor chip C1 on the lower substrate 300 or an interposer (not shown). The connection bump may receive at least one selected from the group consisting of a control signal, a power signal, and a ground signal, which operate the first to third semiconductor chips C1, C2, and C3, from the outside (i.e., externally), may receive a data signal to be stored in the first to third semiconductor chips C1, C2, and C3 from the outside, or may provide data from the first to third semiconductor chips C1, C2, and C3 to the outside.

The second semiconductor chip C2 may be mounted on the top surface of the first semiconductor chip C1 and electrically connected to the first semiconductor chip C1 by the second connection member 224 between the first semiconductor chip C1 and the second semiconductor chip C2.

The second semiconductor chip C2 may include a second semiconductor substrate 220, a second semiconductor device layer, a second through electrode 222, and a second connection pad 223. As shown in FIG. 1, the second semiconductor substrate 220 may include a top surface and a bottom surface opposite to the top surface. The second semiconductor device layer may be formed on the bottom surface of the second semiconductor substrate 220. The second semiconductor device layer may be adjacent to the bottom surface of the second semiconductor substrate 220. The second semiconductor chip C2 may have similar technical characteristics to the first semiconductor chip C1, and thus, detailed descriptions thereof are omitted.

The third semiconductor chip C3 may be mounted on the top surface of the second semiconductor chip C2. The third connection member 234 may be between the second semiconductor chip C2 and the third semiconductor chip C3.

The third semiconductor chip C3 may include a third semiconductor substrate 230, a third semiconductor device layer, and a fourth connection pad 233. Unlike the first semiconductor chip C1 and the second semiconductor chip C2, the third semiconductor chip C3 may not include a through electrode. The thickness of the third semiconductor chip C3 (e.g., in the third direction) may be greater than the thickness of any one of the first semiconductor chip C1 and the second semiconductor chip C2. As shown in FIG. 1, a horizontal width of the first semiconductor chip C1 may be greater than a horizontal width of any one of the second semiconductor chip C2 and the third semiconductor chip C3.

The third semiconductor chip C3 may have similar technical characteristics to the first semiconductor chip C1, and thus, detailed descriptions thereof are omitted.

The lower substrate 300 may include a substrate body 310, lower connection pads 312 on the bottom surface of the substrate body 310, upper connection pads 311 on the top surface of the substrate body 310, and external connection terminals 313 on the lower connection pads 312. The substrate body 310 may include an insulating material and a wiring, which electrically connects the upper connection pads 311 to the lower connection pads 312.

Insulating layers may be arranged among the lower substrate 300, the first semiconductor chip C1, the second semiconductor chip C2, and the third semiconductor chip C3. For example, a first insulating layer 215 may be between the lower substrate 300 and the first semiconductor chip C1, a second insulating layer 225 may be between the first semiconductor chip C1 and the second semiconductor chip C2, and a third insulating layer 235 may be between the second semiconductor chip C2 and the third semiconductor chip C3.

The first insulating layer 215 may be between the lower substrate 300 and the first semiconductor chip C1 and may surround the side surface of a connection bump. It will be understood that “an element A surrounds an element B” (or similar language) as used herein means that the element A is at least partially around the element B but does not necessarily mean that the element A completely encloses the element B. The second insulating layer 225 may be between the first semiconductor chip C1 and the second semiconductor chip C2 and may surround the side surface of the second connection member 224. The third insulating layer 235 may be between the second semiconductor chip C2 and the third semiconductor chip C3 and may surround the side surface of the third connection member 234.

As illustrated in FIG. 1, the side surface of each of the first to third insulating layers 215, 225, and 235 may protrude outward in the first direction by a certain width. However, the inventive concepts are not limited thereto.

In some embodiments, the first to third insulating layers 215, 225, and 235 may include an underfill material, such as an insulating polymer or epoxy resin. In some embodiments, the first to third insulating layers 215, 225, and 235 may include a material that is formed by molded underfill (MUF).

FIG. 2C is a cross-sectional view of the semiconductor package 1 according to some embodiments. Redundant descriptions given above may be omitted for ease of description.

Referring to FIGS. 2A and 2B, connection bumps may be respectively arranged on first connection pads 130 located in the center region CTR, the first side region SD1, and the second side region SD2. The connection bumps may include the extension bump 100T and the non-extension bump 100N.

A connection bump in the center region CTR may be of a different type than a connection bump in any one of the first side region SD1 and the second side region SD2. For example, the extension bump 100T may be arranged on a first connection pad 130 in the center region CTR and the non-extension bump 100N may be arranged on a first connection pad 130 in any one of the first side region SD1 and the second side region SD2. The structure of each of the extension bump 100T and the non-extension bump 100N is described in greater detail below. As used herein, a region in which extension bumps 100T are arranged may also be referred to as a first region.

A plurality of first connection pads 130 may be evenly spaced apart from each other by a first width pitch PX1 in the first direction. Similarly, the first connection pads 130 may be evenly spaced apart from each other by a first length pitch PY1 in the second direction. For example, as shown in FIG. 2A, the first connection pads 130 may be evenly spaced apart from each other by the first width pitch PX1 in the first direction. The first connection pads 130 may be evenly spaced apart from each other by the first length pitch PY1 in the second direction. Although the first connection pads 130 are described to be evenly spaced apart from each other, the inventive concepts are not limited thereto.

A direction of one of the first width pitch PX1 and the first length pitch PY1, which has a smaller value than the other, may be defined as a pitch direction. For example, as shown in FIG. 2A, when the first width pitch PX1 is less than the first length pitch PY1, the first direction in which the first connection pads 130 are spaced apart from each other by the first width pitch PX1 may be defined as a first pitch direction PD1. In other words, a direction in which two adjacent first connection pads 130 are closest to each other may be defined as the first pitch direction PD1. That is, the first pitch direction PD1 may be defined as a direction in which adjacent ones of the first connection pads 130 are closest to each other.

A pitch distance between two adjacent first connection pads 130 in the first pitch direction PD1 may be in a range from about 50 μm to about 100 μm. For example, the first width pitch PX1 in the same direction as the first pitch direction PD1 may be in a range from about 30 μm to about 100 μm. For example, the first width pitch PX1 may be in a range from about 50 μm to about 100 μm. For example, the first width pitch PX1 may correspond to a pitch distance between a first conductive pillar 110 and an adjacent first conductive pillar 110 that is closest thereto. For example, the first width pitch PX1 may correspond to a center-to-center pitch distance between the first conductive pillar 110 and the adjacent first conductive pillar 110 that is closest thereto.

An extension direction may be defined with respect to the extension bump 100T. For example, when the protrusion of the extension bump 100T is vertically arranged in FIG. 2A, a direction in which the protrusion of the extension bump 100T faces may be defined as a first extension direction TBD1. The protrusion of the extension bump 100T may correspond to an extension seed layer 120 having a shape that extends longitudinally in a direction on the horizontal plane, as shown in FIG. 2B. As used herein, the term “longitudinally” indicates a length direction and may correspond to a lengthwise dimension of a referenced element.

For example, as shown in FIG. 2B, the extension seed layer 120 may protrude from a first conductive pillar 110 in the second direction and may thus have a shape longitudinally extending in the second direction. In this case, the second direction in which the extension seed layer 120 longitudinally extends may be the first extension direction TBD1. Unlike the extension bump 100T, the non-extension bump 100N may include a non-extension seed layer having a shape that does not extend beyond a first conductive pillar 110 (e.g., in a plan view). In other words, the non-extension bump 100N may include a non-extension seed layer that does not protrude from a side surface of a first conductive pillar 110 in the second direction. For example, side surfaces of the non-extension seed layer of the non-extension bump 100N may overlap a first conductive pillar 110 of the non-extension bump 100N in the third direction, and the side surfaces of the non-extension seed layer may oppose each other in the second direction. As used herein, “an element A overlaps an element B in a direction X” (or similar language) means that there is at least one line that extends in the direction X and intersects both the elements A and B. The non-extension bump 100N may also include a third seed layer between the non-extension seed layer and one of the first connection pads 130. As used herein, the non-extension seed layer may also be referred to as a first seed layer. As used herein, the first conductive pillar 110 included in the non-extension bump 100N may also be referred to as a second conductive pillar 110. For example, the non-extension seed layer may include chrome (Cr), tungsten (W), copper (Cu), nickel (Ni), aluminum (Al), palladium (Pd), gold (Au), or a combination thereof. For example, the third seed layer of the non-extension bump 100N may include chrome (Cr), tungsten (W), titanium (Ti), copper (Cu), nickel (Ni), aluminum (Al), palladium (Pd), gold (Au), or a combination thereof.

In the semiconductor package 1, the pitch direction may be different from the extension direction. For example, as shown in FIG. 2A, the first pitch direction PD1 may be different from the first extension direction TBD1. The detailed structure of the extension bump 100T is described in greater detail below.

The extension bump 100T may include the first conductive pillar 110, the extension seed layer 120, and a second seed layer 121 (e.g., see FIG. 4A). The extension seed layer 120 may include chrome (Cr), tungsten (W), copper (Cu), nickel (Ni), aluminum (Al), palladium (Pd), gold (Au), or a combination thereof. The second seed layer 121 may include chrome (Cr), tungsten (W), titanium (Ti), copper (Cu), nickel (Ni), aluminum (Al), palladium (Pd), gold (Au), or a combination thereof.

Referring to FIG. 2C, warpage may occur in the first semiconductor chip C1, the second semiconductor chip C2, and the third semiconductor chip C3 of the semiconductor package 1. For example, as shown in FIG. 2C, the first to third semiconductor chips C1, C2, and C3 may have smile-shaped warpage that is convex downwards. When the first to third semiconductor chips C1, C2, and C3 having warpage are mounted on the lower substrate 300, the distance (e.g., in the third direction) between the bottom surface of the first semiconductor chip C1 and the top surface of the lower substrate 300 may not be uniform. For example, the distance between the bottom surface of the first semiconductor chip C1 and the top surface of the lower substrate 300 may decrease toward the center region CTR, as shown in FIG. 2C. The distance between the bottom surface of the first semiconductor chip C1 and the top surface of the lower substrate 300 may be sufficient in the first side region SD1 and the second side region SD2. In this case, the extension bump 100T may be arranged on a first connection pad 130 in the center region CTR. Either the extension bump 100T or the non-extension bump 100N may be arranged in the first side region SD1 and the second side region SD2.

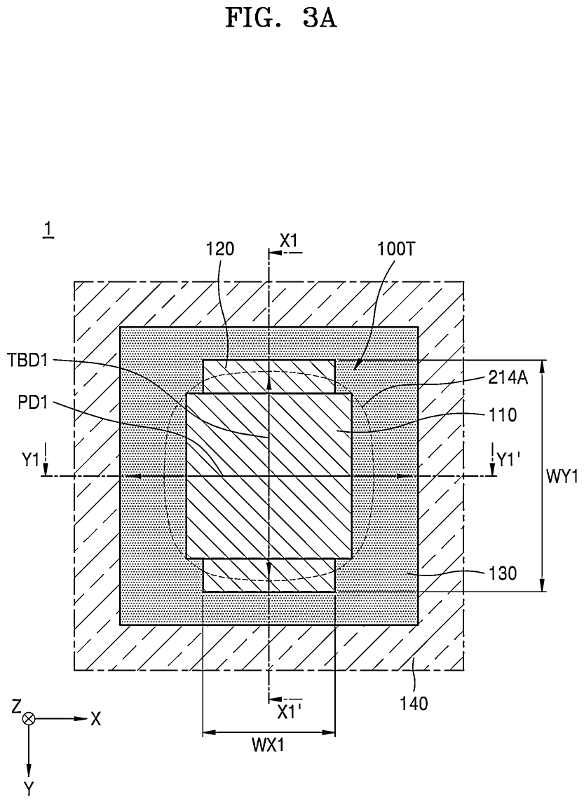

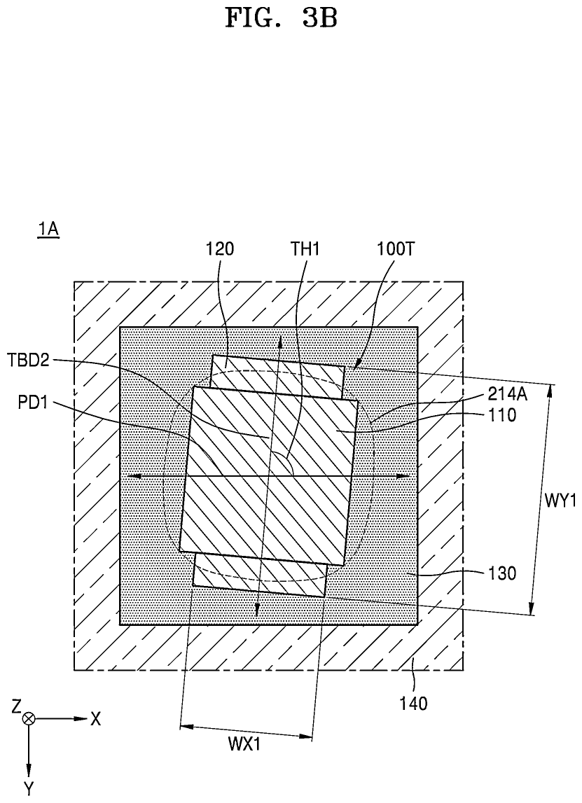

FIG. 3A is an enlarged cross-sectional view of the extension bump 100T in FIG. 2B. FIG. 3B is a cross-sectional view of the extension bump 100T of a semiconductor package 1A, according to some embodiments. FIG. 4A is a cross-sectional view of the extension bump 100T taken along line X1-X1′ in FIG. 3A. FIG. 4B is a cross-sectional view of the extension bump 100T taken along line Y1-Y1′ in FIG. 3A. FIG. 4C is a cross-sectional view of a semiconductor package 1B taken along a line corresponding to line X1-X1′ in FIG. 3A, according to some embodiments. Redundant descriptions given above may be omitted below for ease of description.

Referring to FIGS. 3A, 4A, and 4B, the first connection pad 130 may be arranged on the bottom surface of the first semiconductor substrate 210. The first protective layer 140 on (e.g., covering) a portion of the first connection pad 130 may be arranged on the bottom surface of the first semiconductor substrate 210. For example, the first protective layer 140 may be spaced apart from the extension seed layer 120. The second seed layer 121 may be arranged on the bottom surface of the first connection pad 130. The extension seed layer 120 may be on (e.g., may cover) the bottom surface of the second seed layer 121 and may extend to partially be on (e.g., to partially cover) the bottom surface of the first connection pad 130. The first conductive pillar 110 may be arranged on the bottom surface of the extension seed layer 120. A first connection member 214A may be arranged on an end, e.g., the bottom surface, of the first conductive pillar 110. The first connection member 214A has a schematic shape before the first connection member 214A is electrically connected to the lower substrate 300. The first semiconductor device layer and the first through electrode 212 may be arranged in the first semiconductor substrate 210 inside the first connection pad 130 (e.g., see FIG. 1). The first connection pad 130 may be electrically connected to the first semiconductor device layer and the first through electrode 212. However, for the visibility of the drawings, the first semiconductor device layer and/or the first through electrode 212 is omitted from some drawings.

The extension seed layer 120 may longitudinally extend and protrude from the first conductive pillar 110 in the second direction. Accordingly, as described above, the first extension direction TBD1 in FIG. 3A may be defined with respect to the extension bump 100T. Like in FIG. 2A, the first pitch direction PD1 in FIG. 3A may correspond to the first direction. The first extension direction TBD1 may be different from the first pitch direction PD1. For example, as shown in FIG. 3A, the first extension direction TBD1 may be perpendicular to the first pitch direction PD1.

The first connection pad 130 may be partially covered by the first protective layer 140, and the width of the exposed portion of the first connection pad 130 in the first direction and the width of the exposed portion of the first connection pad 130 in the second direction may be in a range from about 30 μm to about 70 μm. In other words, the shape of the exposed portion of the first connection pad 130 that is not covered by the first protective layer 140 may have a quadrilateral shape, as shown in FIG. 3A, but is not limited thereto.

The extension seed layer 120 may have a shape that longitudinally extends in one direction. For example, as shown in FIG. 3A, a first width WX1 of the extension seed layer 120 may be less than a second width WY1 of the extension seed layer 120. In this case, the second direction may be the first extension direction TBD1. When the first width WX1 of the extension seed layer 120 is less than the second width WY1 of the extension seed layer 120, the length of the extension seed layer 120 may be in the second direction corresponding to the direction of the second width WY1 of the extension seed layer 120. For example, the first width WX1 of the extension seed layer 120 may be in a range from about 10 μm to about 25 μm. The second width WY1 of the extension seed layer 120 may be greater than the first width WX1 of the extension seed layer 120 and may be in a range from about 15 μm to about 35 μm.

Referring to FIG. 3B, unlike in FIG. 3A, a second extension direction TBD2 may not coincide with the second direction in the semiconductor package 1A of FIG. 3B. The second extension direction TBD2 may not be perpendicular to the first pitch direction PD1. A first angle TH1 corresponding to an acute angle between the second extension direction TBD2 and the first pitch direction PD1 may be in a range from about 60° to about 90°.

Referring to FIG. 4C, in the semiconductor package 1B, an extension bump 100T1 may include a first conductive pillar 110, an extension seed layer 120A, and a second seed layer 121A. The horizontal shape of the second seed layer 121A may be the same as the horizontal shape of the extension seed layer 120A. In other words, the second seed layer 121A may have a shape that longitudinally extends in the same direction as the extension seed layer 120A. For example, the extension seed layer 120A and the second seed layer 121A may both protrude from a side surface of the first conductive pillar 110 in the second direction. Accordingly, the extension seed layer 120A may be separated from the first connection pad 130 by the second seed layer 121A in the semiconductor package 1B. In other words, the second seed layer 121A may be between the extension seed layer 120A and the first connection pad 130.

Referring back to FIGS. 1, 2A, and 2B, unlike the extension bump 100T, the non-extension bump 100N may include a non-extension seed layer that does not longitudinally extend in one direction. In other words, the cross-sectional shape of the non-extension bump 100N may be the same as that of the extension bump 100T shown in FIG. 4B regardless of the direction of the cross-section. For example, unlike the extension bump 100T shown in FIG. 4A, the non-extension bump 100N may include a non-extension seed layer that does not protrude from a side surface of a first conductive pillar 110 in the second direction. The difference between the non-extension bump 100N and the extension bump 100T may lie in the difference between the extension seed layer and the non-extension seed layer described above. Description of the non-extension bump 100N that overlaps with the description of the extension bump 100T is omitted for case of description.

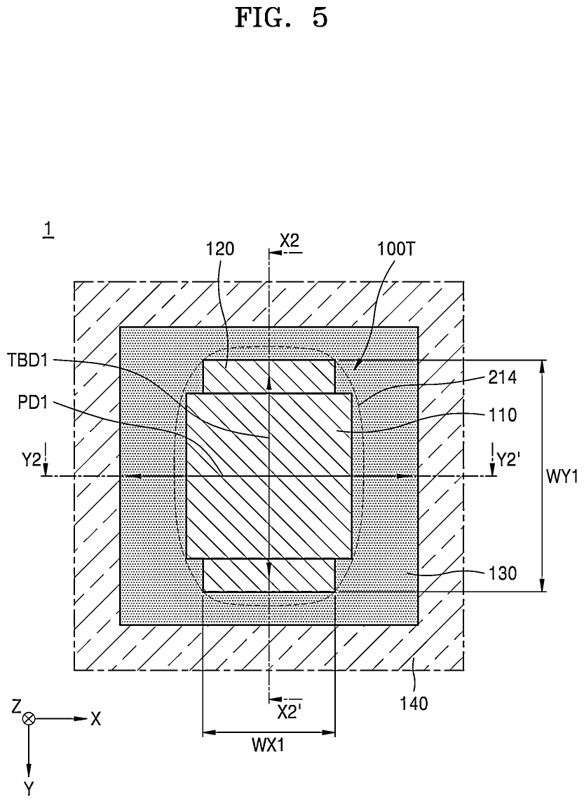

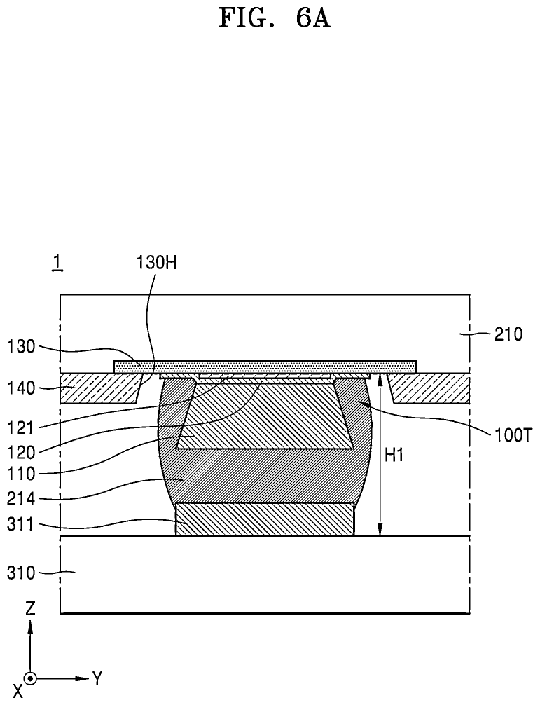

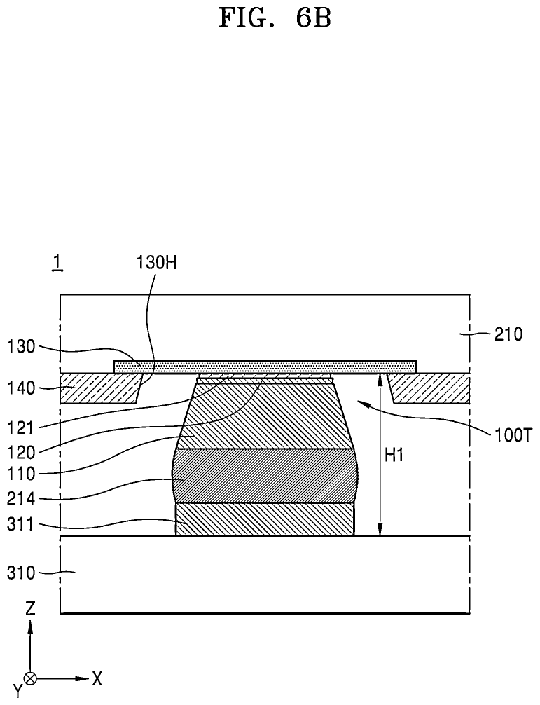

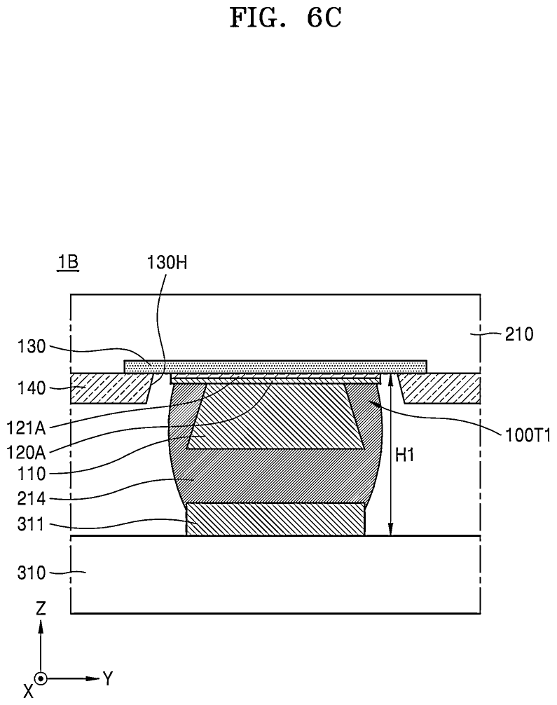

FIG. 5 is an enlarged cross-sectional view of the extension bump 100T in FIG. 2B. FIG. 6A is a cross-sectional view of the extension bump 100T taken along line X2-X2′ in FIG. 5. FIG. 6B is a cross-sectional view of the extension bump 100T taken along line Y2-Y2′ in FIG. 5. FIG. 6C is a cross-sectional view of the semiconductor package 1B taken along a line corresponding to line X2-X2′ in FIG. 5, according to some embodiments. Redundant descriptions given above may be omitted for ease of description.

FIGS. 5, 6A, and 6B show states in which a first connection member 214 is connected to the upper connection pad 311 on the substrate body 310. As described above, the extension seed layer 120 may be on (e.g., may cover) the second seed layer 121 and may partially be on (e.g., may partially cover) the bottom surface of the first connection pad 130. The first connection member 214 may be in contact with the upper connection pad 311 of the lower substrate 300 and may flow along opposite sides of the first conductive pillar 110 to be in contact with the extension seed layer 120 (e.g., see FIG. 6A). As shown in FIG. 6B, the first connection member 214 may not flow along the other sides of the first conductive pillar 110 in a direction other than the extension direction of the extension seed layer 120. In other words, the first connection member 214 may not be on the sides of the first conductive pillar 110 that oppose each other in a direction other than the extension direction of the extension seed layer 120. For example, the first connection member 214 may not be on the sides of the first conductive pillar 110 that oppose each other in the first direction. As shown in FIG. 5, the extension direction of the extension seed layer 120 is in the second direction. However, the inventive concepts are not limited thereto. Although not shown in FIGS. 5, 6A, and 6B, a first connection member 214 may also be electrically connected between an upper connection pad 311 on the substrate body 310 and a first conductive pillar 110 of the non-extension bump 100N. The first connection member 214 may be in contact with the first conductive pillar 110 of the non-extension bump 100N. Unlike the extension bump 100T shown in FIG. 6A, the first connection member 214 may not be in contact with (i.e., may be separated from) the non-extension seed layer of the non-extension bump 100N. As used herein, a first connection member 214 that is in contact with a first conductive pillar 110 of the non-extension bump 100N may also be referred to as a second connection member 214.

The distance (e.g., in the third direction) between the top surface of the lower substrate 300 and the bottom surface of the first connection pad 130, on which the extension bump 100T is arranged, may be in a range from about 30 μm to about 70 μm. In other words, the distance between the top surface of the lower substrate 300 and the bottom surface of the first connection pad 130 may be in a range from about 30 μm to about 70 μm in the first region. A first separation height H1 may be substantially equal to the distance between the bottom surface of the first semiconductor substrate 210 and the top surface of the lower substrate 300. For example, the first separation height H1 may be in a range from about 30 μm to about 70 μm. As described above, when warpage occurs in the first semiconductor substrate 210, the first separation height H1 may vary depending on the location.

The first connection member 214 may include a solder ball. The first connection member 214 may include tin (Sn), indium (In), bismuth (Bi), antimony (Sb), copper (Cu), silver (Ag), zinc (Zn), lead (Pb), and/or an alloy thereof. For example, the first connection member 214 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and/or Sn—Bi—Zn. The first connection member 214 may be connected to the upper connection pad 311 of the lower substrate 300 by a thermal compression process. In this process, the first connection member 214 may undergo melting and solidification.

In the absence of the extension seed layer 120, the first connection member 214 may melt and randomly overflow laterally. The lateral overflow of the first connection member 214 may occur when the first semiconductor chip C1 is too close to the lower substrate 300 due to the warpage of the first to third semiconductor chips C1, C2, and C3, as described above. In other words, in FIG. 2C, the first connection member 214 near the center region CTR is highly likely to overflow laterally.

The first connection member 214 overflowing laterally may contact another first connection member 214, thereby forming a bridge, which may cause failure of one or more of the first to third semiconductor chips C1, C2, and C3. However, according to some embodiments, the semiconductor package 1 may include the extension seed layer 120, and accordingly, the first connection member 214 that melts and overflows may contact the extension seed layer 120, which includes a material having a relatively high adhesion to the first connection member 214, and may be solidified on the extension seed layer 120. For example, the first connection member 214 may contact the extension seed layer 120 in the shape shown in FIG. 6A. Accordingly, a bridge may not be formed between two adjacent first connection members 214. In other words, the reliability of the semiconductor package 1 may be increased through the extension bump 100T thereof.

In the case of FIG. 3B, the first angle formed by the second extension direction TBD2 and the first pitch direction PD1 may not be 90°. Although the second extension direction TBD2 is not perpendicular to the first pitch direction PD1, the first connection member 214 may be in contact with the extension seed layer 120 and connected to the upper connection pad 311 of the lower substrate 300, as described above. The second extension direction TBD2, in which the extension seed layer 120 longitudinally extends, may differ from the first pitch direction PD1 by at least 60°, and accordingly, the possibility of failure including a short-circuit between two adjacent first connection pads 130 may be reduced.

Referring to FIG. 6C, like in FIG. 4C, the horizontal shape of the second seed layer 121A may be the same as the horizontal shape of the extension seed layer 120A in the semiconductor package 1B of FIG. 6C. In other words, the second seed layer 121A may have a shape that longitudinally extends in the same direction as the extension seed layer 120A. For example, the extension seed layer 120A and the second seed layer 121A may both protrude from a side surface of the first conductive pillar 110 in the second direction.

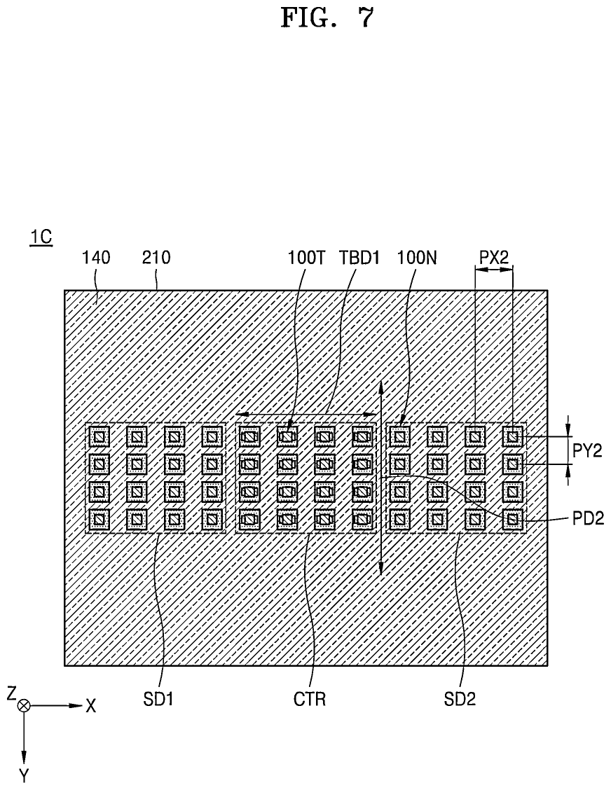

FIG. 7 is a cross-sectional view of a semiconductor package 1C taken along a line corresponding to line Z1-Z1′ in FIG. 1, according to some embodiments. Redundant descriptions given above may be omitted for ease of description.

Referring to FIG. 7, unlike the semiconductor package 1 of FIG. 2A, a second pitch direction PD2 may correspond to the second direction and the first extension direction TBD1 may correspond to the first direction in the semiconductor package 1C of FIG. 7. A second width pitch PX2 may be greater than a second length pitch PY2. Accordingly, a pitch direction in the semiconductor package 1C may be defined as the second pitch direction PD2 that is the same as the second direction corresponding to the second length pitch PY2. When the second pitch direction PD2 corresponds to the second direction, the extension seed layer 120 of each of the extension bumps 100T, which are arranged in the center region CTR to prevent failure occurring due to interference between two adjacent first connection pads 130, may protrude in the first direction instead of the second direction. Accordingly, when the pitch direction changes, the extension direction of the extension bumps 100T may also be changed according to the pitch direction.

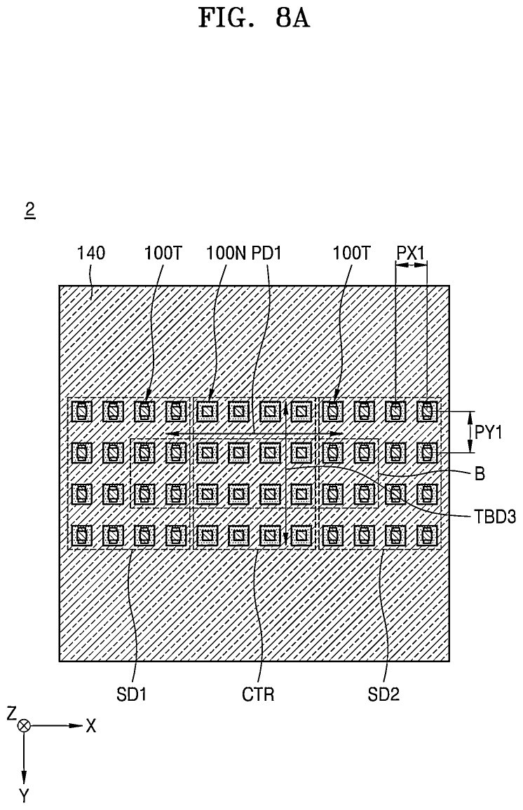

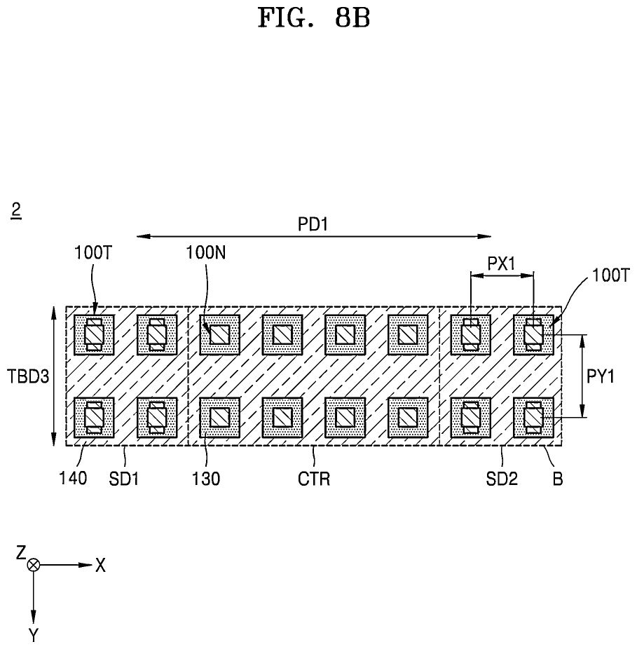

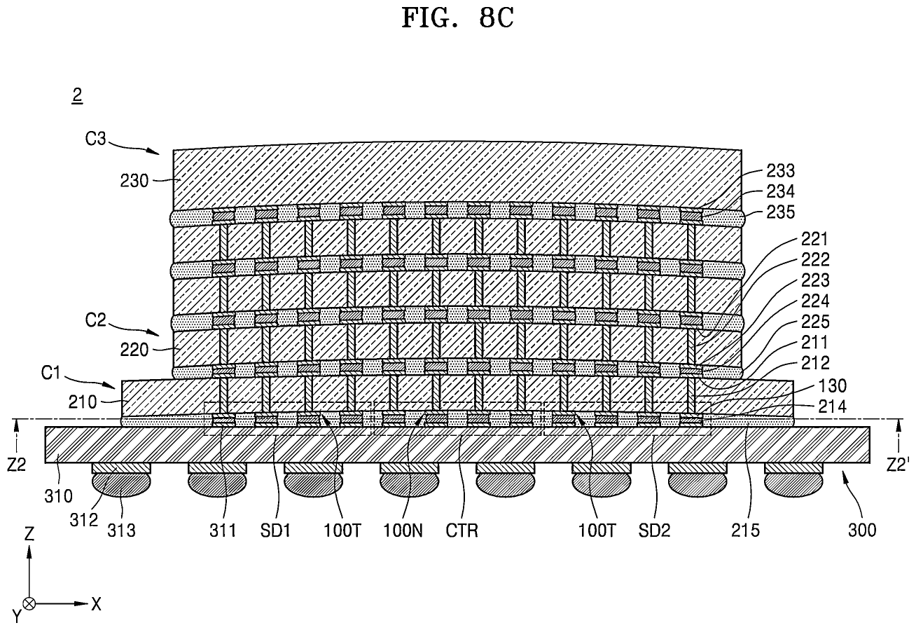

FIG. 8A is a cross-sectional view of a semiconductor package 2, taken along line Z2-Z2′ in FIG. 8C, according to some embodiments. FIG. 8B is an enlarged view of a region B in FIG. 8A. FIG. 8C is a cross-sectional view of the semiconductor package 2 according to some embodiments. Redundant descriptions given above may be omitted for ease of description.

Referring to FIGS. 8A to 8C, a connection bump in the center region CTR may be of a different type than a connection bump in any one of the first side region SD1 and the second side region SD2. For example, the non-extension bump 100N may be arranged on a first connection pad 130 in the center region CTR, and the extension bump 100T may be arranged on a first connection pad 130 in any one of the first side region SD1 and the second side region SD2. The descriptions of the first width pitch PX1, the first length pitch PY1, the first pitch direction PD1, and a third extension direction TBD3 are the same as those given above with reference to FIGS. 2A and 2B.

Warpage may occur in the first semiconductor chip C1, the second semiconductor chip C2, and the third semiconductor chip C3 of the semiconductor package 2. For example, as shown in FIG. 8C, the first to third semiconductor chips C1, C2, and C3 may have sad face-shaped warpage that is convex upwards. When the first to third semiconductor chips C1, C2, and C3 that have warpage are mounted on the lower substrate 300, the distance (e.g., in the third direction) between the bottom surface of the first semiconductor chip C1 and the top surface of the lower substrate 300 may not be uniform. For example, the distance between the bottom surface of the first semiconductor chip C1 and the top surface of the lower substrate 300 may decrease toward the first side region SD1 and the second side region SD2, as shown in FIG. 8C.

Accordingly, the non-extension bump 100N may be arranged on a first connection pad 130 in the center region CTR, and the extension bump 100T may be arranged on a first connection pad 130 in any one of the first side region SDI and the second side region SD2. The extension direction of the extension bump 100T may correspond to the third extension direction TBD3 that is different from the first pitch direction PD1. Through this arrangement of the extension bump 100T, the possibility of failure, such as a short-circuit caused by the short distance between the first connection pad 130 and the upper connection pad 311 of the lower substrate 300, may be decreased in the semiconductor package 2. Accordingly, the reliability of the semiconductor package 2 may be increased.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

While the inventive concepts have been particularly shown and described with reference to example embodiments thereof, it will be understood that various changes in form and details may be made therein without departing from the scope of the following claims.

What is claimed is:

1. A semiconductor package comprising:
a semiconductor substrate;
connection pads on a bottom surface of the semiconductor substrate; and
connection bumps respectively on the connection pads,
wherein the connection bumps include an extension bump and a non-extension bump,
wherein the extension bump includes an extension seed layer on a respective one of the connection pads and a first conductive pillar on the extension seed layer, and
wherein the extension seed layer longitudinally extends in a first extension direction.

2. The semiconductor package of claim 1, wherein the extension bump is in a first region of the semiconductor substrate and the non-extension bump is in a second region of the semiconductor substrate that is different from the first region.

3. The semiconductor package of claim 2, wherein an angle is defined between the first extension direction and a pitch direction,
wherein the pitch direction is a direction in which adjacent ones of the connection pads are closest to each other, and
wherein the angle is in a range from about 60° to about 90°.

4. The semiconductor package of claim 1, wherein the extension bump further includes a second seed layer between the extension seed layer and the respective one of the connection pads.

5. The semiconductor package of claim 4, wherein the extension seed layer is in contact with a surface of the second seed layer and a portion of a surface of the respective one of the connection pads.

6. The semiconductor package of claim 4, wherein the extension seed layer is spaced apart from the respective one of the connection pads, and
wherein the second seed layer is between the extension seed layer and the respective one of the connection pads.

7. The semiconductor package of claim 4, wherein the extension seed layer includes copper (Cu), and
wherein the second seed layer includes titanium (Ti).

8. The semiconductor package of claim 2, wherein the first region includes a horizontal center portion of the bottom surface of the semiconductor substrate.

9. The semiconductor package of claim 2, wherein the first region includes at least a portion of the bottom surface of the semiconductor substrate that is laterally spaced apart from a horizontal center portion of the bottom surface of the semiconductor substrate.

10. The semiconductor package of claim 3, wherein the angle is 90°.

11. The semiconductor package of claim 1, further comprising a through silicon via (TSV) extending into the semiconductor substrate, wherein the semiconductor substrate comprises a memory device.

12. The semiconductor package of claim 3, wherein the non-extension bump includes a first seed layer on another respective one of the connection pads and a second conductive pillar on the first seed layer, and
wherein the first seed layer does not protrude from a side surface of the second conductive pillar in the first extension direction.

13. The semiconductor package of claim 12, further comprising a lower substrate on the bottom surface of the semiconductor substrate,
wherein upper connection pads are on a top surface of the lower substrate,
wherein a first connection member is electrically connected between a first one of the upper connection pads and the first conductive pillar and is in contact with the extension seed layer and an end of the first conductive pillar,
wherein a second connection member is electrically connected between a second one of the upper connection pads and the second conductive pillar and is in contact with the second conductive pillar, and
wherein the second connection member is separated from the first seed layer.

14. The semiconductor package of claim 13, wherein a pitch distance that corresponds to a distance between the first conductive pillar in the first region and another conductive pillar closest to the first conductive pillar is in a range from about 50 μm to about 100 μm, and
wherein a distance between the bottom surface of the semiconductor substrate and the top surface of the lower substrate is in a range from about 30 μm to about 70 μm.

15. The semiconductor package of claim 1, further comprising a protective layer on the bottom surface of the semiconductor substrate,
wherein the protective layer is on a portion of each of the connection pads and is spaced apart from the extension seed layer.

16. A semiconductor package comprising:
a first semiconductor chip including a first semiconductor substrate, first connection pads on a bottom surface of the first semiconductor substrate, connection bumps respectively on the first connection pads, and a through silicon via (TSV) extending into the first semiconductor substrate; and
a second semiconductor chip on the first semiconductor chip, the second semiconductor chip including a second semiconductor substrate and a TSV extending into the second semiconductor substrate,
wherein the connection bumps include an extension bump and a non-extension bump,
wherein the extension bump includes an extension seed layer on a respective one of the first connection pads and a first conductive pillar on the extension seed layer,
wherein the extension seed layer longitudinally extends in a first extension direction,
wherein an angle is defined between the first extension direction and a pitch direction,
wherein the pitch direction is a direction in which adjacent ones of the first connection pads are closest to each other, and
wherein the angle is in a range from about 60° to about 90°.

17. The semiconductor package of claim 16, wherein the extension bump is in a first region of the first semiconductor substrate and the non-extension bump is in a second region of the first semiconductor substrate that is different from the first region.

18. The semiconductor package of claim 17, wherein the non-extension bump includes a first seed layer on another respective one of the first connection pads and a second conductive pillar on the first seed layer, and
wherein the first seed layer does not protrude from a side surface of the second conductive pillar in the first extension direction.

19. The semiconductor package of claim 18, further comprising a lower substrate on the bottom surface of the first semiconductor substrate,
wherein upper connection pads are on a top surface of the lower substrate,
wherein a first connection member is electrically connected between a first one of the upper connection pads and the first conductive pillar and is in contact with the extension seed layer and an end of the first conductive pillar,
wherein a second connection member is electrically connected between a second one of the upper connection pads and the second conductive pillar and is in contact with the second conductive pillar, and
wherein the second connection member is separated from the first seed layer.

20. A semiconductor package comprising:
a first semiconductor chip including a first semiconductor substrate that comprises a memory device, first connection pads on a bottom surface of the first semiconductor substrate, connection bumps respectively on the first connection pads, and a through silicon via (TSV) extending into the first semiconductor substrate;
a second semiconductor chip on the first semiconductor chip, the second semiconductor chip including a second semiconductor substrate and a TSV extending into the second semiconductor substrate; and
a lower substrate on the bottom surface of the first semiconductor substrate,
wherein the connection bumps include an extension bump and a non-extension bump,
wherein the extension bump is in a first region of the first semiconductor substrate and the non-extension bump is in a second region of the first semiconductor substrate that is different from the first region,
wherein the extension bump includes an extension seed layer on a respective one of the first connection pads, a first conductive pillar on the extension seed layer, and a second seed layer between the extension seed layer and the respective one of the first connection pads,
wherein the non-extension bump includes a first seed layer on another respective one of the first connection pads, a third seed layer between the first seed layer and the another respective one of the first connection pads, and a second conductive pillar on the first seed layer,
wherein the extension seed layer longitudinally extends in a first extension direction, and the first seed layer does not protrude from a side surface of the second conductive pillar in the first extension direction,
wherein the first extension direction is perpendicular to a pitch direction,
wherein the pitch direction is a direction in which adjacent ones of the first connection pads are closest to each other,
wherein the extension seed layer and the first seed layer include copper (Cu),
wherein the second seed layer and the third seed layer include titanium (Ti),
wherein upper connection pads are on a top surface of the lower substrate,
wherein a first connection member is electrically connected between a first one of the upper connection pads and the first conductive pillar and is in contact with the extension seed layer and an end of the first conductive pillar,
wherein a second connection member is electrically connected between a second one of the upper connection pads and the second conductive pillar and is in contact with the second conductive pillar,
wherein the second connection member is separated from the first seed layer, and
wherein a pitch distance that corresponds to a distance between the first conductive pillar in the first region and another conductive pillar closest to the first conductive pillar is in a range from about 50 μm to about 100 μm, and a distance between the bottom surface of the first semiconductor substrate and the top surface of the lower substrate is in a range from about 30 μm to about 70 μm.
